(19) United States
(12) Patent Application Publication
(10) Pub. No.: US 2006/0028250 A1
(43) Pub. Date: Feb. 9, 2006

(54) Frequency converter circuit

(75) Inventors: Herbert Knapp, Munich (DE); Martin Wurzer, Munich (DE)

Correspondence Address: DARBY & DARBY P.C., P. O. BOX 5257, NEW YORK, NY, 10150-5257, US

(73) Assignee: Infineon Technologies AG, Munich (DE)

(21) Appl. No.: 11/149,450

(22) Filed: Jun. 8, 2005

(30) Foreign Application Priority Data
Jun. 8, 2004 (DE) 10 2004 027 809.1

(51) Int. Cl. H03B 19/00

(52) U.S. Cl. 327/113

(57) ABSTRACT

A frequency converter circuit having at least one frequency converter element and a load stage. The frequency converter element has at least one signal input and at least one signal output, the frequency converter element being set up such that a signal provided at the signal output has a different signal frequency than a signal fed in at the signal input. The load stage has at least one nonreactive resistor coupled between the frequency converter element and a power feeding terminal and at least one inductance coupled in series with said resistor, and at least one capacitance whose first terminal is coupled between the nonreactive resistor and the inductance and whose second terminal is coupled to a power supply terminal.

### CROSS-REFERENCE TO RELATED APPLICATION

This application claims priority to German Patent Application Serial No. 10 2004 027 809.1-31, which was filed on Jun. 8, 2004.

### FIELD OF THE INVENTION

The invention relates to a frequency converter circuit and a frequency converter circuit arrangement.

### BACKGROUND OF THE INVENTION

A frequency converter circuit is an electronic circuit in which at least one input signal having an input frequency is fed into the electronic circuit and is converted into an output signal having an output frequency by the electronic circuit, the value of the input frequency and the value of the output frequency differing from one another.

A frequency converter circuit which converts an input frequency into an output frequency, the value of the input frequency and the value of the output frequency being in a fixedly predetermined ratio to one another, is referred to as a frequency divider circuit. Basic circuit elements for a frequency converter circuit which realize a frequency divider circuit are flip-flop circuits.

A flip-flop is a bistable multivibrator, i.e. a digital circuit. The output voltage of a bistable multivibrator changes between two predetermined values, which are designated by the logic values “0” and “1” in the sense of Boolean algebra. The process of toggling between the two logic values is triggered with the aid of an input signal in the form of a short pulse. Tietze, U., Schenk, Ch.: “Halbleiter-Schaltungstechnik” [“Semiconductor circuitry”], Springer-Verlag, 11th edition, ISBN 3-540-64192-0, pp. 685-712, (1999), discloses a causal linkage between an input signal and an output signal by means of logic gates which establish linkages between the input signal and the output signal in accordance with Boolean algebra. The logic gates are realized at the transistor level or diode level. Customary technologies of gate realizations are emitter coupled logic (ECL), current mode logic (CML), complementary metal oxide semiconductor (CMOS), resistor-transistor logic (RTL), diode-transistor logic (DTL), low-speed interference-proof logic (LSL), transistor-transistor logic (TTL), open-collector technique, tristate technique, wired-OR combination and also NMOS logic. Flip-flop switching mechanisms based on ECL have bipolar transistors in addition to nonreactive resistors. Flip-flop switching mechanisms based on CMOS technology or NMOS technology or on a combination of both technologies additionally have field effect transistors besides nonreactive resistors.

There are transparent flip-flop circuits. Transparent flip-flop circuits are flip-flop circuits which process the input signal without buffer storage and enable it immediately at the output. Furthermore, flip-flop circuits with buffer storage, which buffer-store the input signal and transfer it to the output only if the inputs have already been latched again, are described in Tietze, U., Schenk, Ch.: “Halbleiter-Schaltungstechnik” [“Semiconductor circuitry”], Springer-Verlag, 11th edition, ISBN 3-540-64192-0, pp. 685-712, (1999).

One example of transparent flip-flop circuits is simple RS flip-flop circuits. An RS flip-flop circuit has a SET input S and a RESET input R, and also a first output, at which an output signal Q is provided, and a second output, at which the inverted output signal QN with respect to the output signal Q is provided. An RS flip-flop circuit which reacts to an applied input signal only at a specific time is often required. This time is determined by an additional clock variable, i.e. an applied clock signal, often designated by CLK, the RS flip-flop circuit clocked with the clock signal being referred to as a statically clocked RS flip-flop circuit. If, in the case of a statically clocked RS flip-flop circuit, the set input S is occupied by a data input signal D and the RESET input R is occupied by the inverted data input signal DN, this gives rise to a clock-state-controlled latch cell (DATA LATCH), which is also referred to as a transparent D-flip-flop circuit.

A nontransparent flip-flop circuit is usually formed from two flip-flops: the “master” flip-flop at the input and the “slave” flip-flop at the output. One example of a master-slave flip-flop circuit is the JK flip-flop circuit: a JK flip-flop circuit has two statically clocked RS flip-flop circuits, the two statically clocked RS flip-flop circuits being latched complementarily with respect to one another by the clock signal CLK. As long as the clock signal CLK=1 (“high”), the input information, i.e. the input signal present at the input, is read into the master flip-flop. The output state, i.e. the output signal provided at the output, remains unchanged in this case since the slave flip-flop is blocked. If the clock signal changes to CLK=0 (“low”), the master flip-flop is blocked, and the state of the flip-flop circuit established directly before the negative clock signal edge is frozen in this way. At the same time the slave flip-flop is enabled and the state of the master flip-flop is thus transferred to the output of the JK flip-flop circuit. The data transfer thus takes place upon the negative clock edge; however, there is no clock state in the case of which the input data, i.e. the applied input signal, directly affect the output, as is the case with a transparent flip-flop circuit.

The input combination R=S=1 leads to an undefined behavior because the negated input signals SN and RN in the master flip-flop simultaneously undergo transition from “00” to “11” if the clock signal becomes CLK =0.

In order to expediently utilize this input combination, the complementary output data of the slave flip-flop are additionally applied to the input gates of the master flip-flop with the aid of a feedback. The additional feedback inputs on the master flip-flop are usually designated as J input and K input. The output state, i.e. the output signal provided for J=K=1 is inverted upon each clock pulse. This is tantamount to a frequency division by the value two. Therefore, a JK master-slave flip-flop circuit permits a particularly simple construction of a frequency divider.

Flip-flop circuits with buffer storage can also be realized by connecting two transparent D-type flip-flop circuits in series and driving them with a complementary clock signal, the flip-flop circuit thereby formed being referred to as a master-slave D-type flip-flop circuit. As long as the clock signal CLK=0, the master flip-flop follows the input signal and Q=D ensues. The slave flip-flop stores the old state. If the clock signal CLK undergoes transition to the value 1, the data information D present at this point in time is “frozen” in the master flip-flop and transferred to the slave flip-flop and thus to the Q output. The data information present at the D input upon the positive clock edge is thus transferred to the Q output. For the rest of the time, the state of the D input, i.e. the input signal present at the D input, has no influence on the output signal provided.

A single-edge-triggered D flip-flop circuit can also be operated as a so-called toggle flip-flop circuit. For this purpose, the inverted output QN is connected to the data input D. The output state is then inverted upon each positive clock edge of the clock signal CLK. A toggle flip-flop circuit constitutes a fundamental component for a frequency divider circuit. A frequency divider circuit can be realized by constructing a chain of flip-flop circuits and coupling the clock input thereof in each case to the output Q of the preceding flip-flop circuits in the signal flow direction. In order to produce a frequency dividing function, the flip-flops must change their output state if the clock signal CLK respectively fed to them undergoes transition from “1” to “0”. Consequently, edge-controlled flip-flop circuits are usually used, e.g. JK master-slave flip-flop circuits where J=K=1. The frequency divider circuit can be extended arbitrarily, in principle. With ten flip-flop circuits coupled in series, the input signal clock frequency of the clock signal present at the first flip-flop circuit can already be halved ten times in this way. A flip-flop circuit which triggers on positive clock edges, that is to say e.g. a single-edge-triggered D-type flip-flop circuit, can also be used.

The frequency of the output signal provided at the output of the first flip-flop circuit is half the frequency of the input signal applied to the input of the first flip-flop circuit. A signal whose frequency is a quarter of the frequency of the input signal applied to the input of the first flip-flop circuit is provided at the output of the second flip-flop circuit, a signal whose frequency is an eighth of the frequency of the input signal applied to the input of the first flip-flop circuit is provided at the output of the third flip-flop circuit, etc. Many frequency divider circuits make use of this frequency divider property of toggle flip-flops.

A frequency divider circuit is thus often based on flip-flop circuits, transparent D-type flip-flop circuits in which the inverted output signal is fed back to the data input often being used in order to obtain very high operating frequencies.

In contrast to a static frequency divider circuit, a dynamic frequency divider circuit has a lower limiting frequency. A static frequency divider circuit is realized with the aid of flip-flop circuits and can be operated at arbitrarily low frequencies provided that the rise time of the clock signal CLK is sufficiently short. Depending on functioning and dimensioning, a dynamic frequency divider circuit operates in a frequency conversion interval of a few percent up to more than one octave relative to the signal frequency of the input signal fed in. However, it can often be operated at substantially higher operating frequencies than a static frequency divider circuit, the maximum operating frequency of which is restricted by the so-called gate delay time τ to a value of

$${f}_{max} \leq \frac{1}{2 \cdot τ} \qquad ( 1 )$$

A dynamic frequency divider circuit is usually based on the principle of regenerative frequency division or on two inverter stages that are changed over alternately by the clock signal CLK, as described for example in Knapp, J.: “Realisierung optimierter monolithisch integrierter Oszillatoren und Frequenzteiler fur Mikrowellen in Si-und SiGe-Technologie”, [“Realization of optimized monolithically integrated oscillators and frequency dividers for microwaves in Si and SiGe technology”], Dissertation E 389 at the Institute for Telecommunications Engineering and Radiofrequency Engineering at the Technical University of Vienna, Faculty for Electrical Engineering, p. 89, October 1999.

Lao, Z., Bronner, W., Thiede, A., Schlechtweg, M., Hulsmann, A., Rieger-Motzer, M., Kaufel, G., Raynor, B., Sedler, M.: “35-GHZ Static and 48 GHz Dynamic Frequency Divider ICs Using 0.2-□m AlGaAs/GaAs-HEMTs”. IEEE Journal of Solid-State Circuits, vol. 32, No. 10, pp. 1556-1562, (October 1997), and Lee, Q., Guthrie, J., Jaganathan, S., Mathew, T., Betser, Y., Krishnan, S., Ceran, S., Rodwell, M. J. W.: “56 GHz Static Frequency Divider in Transferred-substrate HBT Technology”, IEEE Radio Frequency IC (RFIC) Symposium, pp. 87-90, (1995), disclose dynamic and static frequency converter circuits, respectively, which are based on flip-flop circuits and have High Electron Mobility Transistors (HEMTs) and Heterojunction Bipolar Transistors (HBTs), respectively. A restriction of the maximum operating frequency of these circuits results from parasitic device and metallization capacitances in parallel with the nonreactive load resistances of the load stages of the frequency converter circuits.

These parasitic capacitances are taken into consideration, as illustrated in FIG. 2 and FIG. 3, by means of a fictitious parasitic capacitance that is taken into account. On account of said parasitic capacitance the magnitude of the load impedance decreases at high operating frequencies. As a result, the voltage swing at the output of the frequency converter circuit decreases at high operating frequencies to an extent such that correct functioning of the frequency divider circuit is often no longer ensured.

Moreover, the parasitic capacitance brings about an additional phase shift, which causes a temporal delay of the output signal and thus likewise reduces the maximum operating frequency of the frequency divider circuit.

In order to be able to illustrate the circuit design of load stages of frequency divider circuits as practiced hitherto in accordance with the prior art, a frequency converter circuit is divided into frequency converter elements. The frequency converter elements are divided into a load stage and a second stage.

Two examples of circuitry realizations of a load stage in accordance with the prior art, as described in Klar, H.: “Integrierte Digitale Schaltungen MOS/BICMOS” [“Integrated digital circuits MOS/BICMOS”], Springer-Verlag, 2nd edition, ISBN 3 540 61284 X, pp. 106-114., (1996), and Lao, Z., et al., are illustrated in FIG. 2 and FIG. 3.

One example of a circuitry realization of a load stage within a frequency converter circuit in accordance with the prior art is illustrated in FIG. 1.

The parasitic effects of the frequency converter element are preferably simulated in the form of a fictitious parasitic capacitance in the load stage of the frequency converter circuit, a nonreactive resistor being a load resistance of the frequency converter circuit.

The parasitic effects of the frequency converter element are simulated in the form of a fictitious parasitic capacitance in a load stage of a frequency converter circuit, a nonreactive resistor being a load resistance of the frequency converter element.

FIG. 2 shows a first circuitry realization of a load stage 200 of frequency converter circuits having a nonreactive resistor 202 arranged between a first node 203 and a second node 204. A fictitious parasitic capacitance C₀ 201 is arranged between the first node 203 and the second node 204. The second node 204 is at ground potential. The load stage which is shown in FIG. 1 and is explained in more detail below is coupled to the second stage of the frequency converter element at the first node 203.

In accordance with a second circuitry realization of a load stage 300 of frequency converter circuits as shown in FIG. 3, an inductance 302 is arranged between a first node 304 and a second node 305. A nonreactive resistor 303 is arranged between the second node 305 and a third node 306. A fictitious parasitic capacitance 301 is arranged between the first node 304 and the third node 306. While the third node 306 is grounded, the load stage is coupled to the second stage of the frequency converter element at the first node 304.

The inductance 302 serves, on the one hand, to keep the magnitude of the load impedance of the frequency converter element large preferably at high operating frequencies and, on the other hand, to keep the phase shift of the load impedance of the frequency converter element as small as possible preferably at high operating frequencies.

FIG. 1 illustrates a known frequency converter circuit arrangement. In the frequency converter circuit arrangement, the load stage of the frequency converter elements is realized in the form of nonreactive resistors and the second stage is realized in the form of NMOS transistor logic.

The frequency converter circuit arrangement clearly represents a single-edge-triggered master-slave D-type flip-flop circuit 100.

A first nonreactive resistor 101 is arranged between a first node 119 and a second node 120. A second nonreactive resistor 102 is arranged between the first node 119 and a third node 121. A third nonreactive resistor 103 is arranged between the first node 119 and a fourth node 127. A fourth nonreactive resistor 104 is arranged between the first node 119 and a fifth node 126. The drain/source region of a first transistor 105 is arranged between the second node 120 and a sixth node 122. The gate region of the first transistor 105 is connected to a seventh node 124. The drain/source region of a second transistor 106 is arranged between the third node 121 and the sixth node 122. The gate region of the second transistor 106 is connected to an eighth node 125. The drain/source region of a third transistor 107 is arranged between the second node 120 and a ninth node 123. The gate region of the third transistor 107 is connected to the third node 121. The drain/source region of a fourth transistor 108 is arranged between the third node 121 and the ninth node 123. The gate region of the fourth transistor 108 is connected to the second node 120. The drain/source region of a fifth transistor 109 is arranged between the fourth node 127 and a tenth node 128. The gate region of the fifth transistor 109 is connected to the third node 121. The drain/source region of a sixth transistor 110 is arranged between the fifth node 126 and the tenth node 128. The gate region of the sixth transistor 110 is connected to the second node 120. The drain/source region of a seventh transistor 111 is arranged between the fourth node 127 and an eleventh node 129. The gate region of the seventh transistor 111 is connected to the fifth node 126. The drain/source region of an eighth transistor 112 is arranged between the fifth node 126 and the eleventh node 129. The gate region of the eighth transistor 112 is connected to the fourth node 127. The drain/source region of a ninth transistor 113 is arranged between the sixth node 122 and a twelfth node 130. The gate region of the ninth transistor 113 is connected to a thirteenth node 133. The drain/source region of a tenth transistor 114 is arranged between the ninth node 123 and the twelfth node 130. The gate region of the tenth transistor 114 is connected to a fourteenth node 131. The drain/source region of an eleventh transistor 115 is arranged between the tenth node 128 and a fifteenth node 132. The gate region of the eleventh transistor 115 is connected to the fourteenth node 131. The drain/source region of a twelfth transistor 116 is arranged between the eleventh node 129 and the fifteenth node 132. The gate region of the twelfth transistor 116 is connected to the thirteenth node 133. A first constant-current source 117 is arranged between the twelfth node 130 and a sixteenth node 134. A second constant-current source 118 is arranged between the fifteenth node 132 and the sixteenth node 134. A signal FIG. is provided at the first node 119, FIG. representing a supply voltage of the frequency converter circuit. A signal D is provided at the seventh node 124. A signal D is provided in inverted fashion at the eighth node 125. A signal CLK is provided at the thirteenth node 133, the signal CLK representing a clock signal. The signal CLK is provided in inverted fashion at the fourteenth node 131. A signal VSS is provided at the sixteenth node 134, VSS representing a further supply voltage of the frequency converter circuit. A signal Q is output at the fifth node 126. A signal Q is output in inverted fashion at the fourth node 127.

The load stage of the frequency converter circuit is isolated from the second stage of the frequency converter circuit by the second node 120, the third node 121 and the fourth node 127 and the fifth node 126.

The load stage of the frequency converter circuit has the first nonreactive resistor 101, the second nonreactive resistor 102, the third nonreactive resistor 103 and the fourth nonreactive resistor 104. The second stage of the frequency converter circuit has the first n-channel MOSFET 105, the second n-channel MOSFET 106, the third n-channel MOSFET 107, the fourth n-channel MOSFET 108, the fifth n-channel MOSFET 109, the sixth n-channel MOSFET 110, the seventh n-channel MOSFET 111, the eighth n-channel MOSFET 112, the ninth n-channel MOSFET 113, the tenth n-channel MOSFET 114, the eleventh n-channel MOSFET 115, the twelfth n-channel MOSFET 116, the first constant-current source 117 and the second constant-current source 118, which serve to put the frequency converter circuit at its operating point.

The second stage can be divided into the following subcircuits:
master D-type flip-flop subcircuit:
   the first n-channel MOSFET 105, the second n-channel MOSFET 106, the third n-channel MOSFET 107, the fourth n-channel MOSFET 108, the ninth n-channel MOSFET 113 and the tenth n-channel MOSFET 114 clearly form a logic gate, the data input signal D provided at the seventh node 124 and the eighth node 125 and the clock input signal CLK provided at the fourteenth node 131 and the thirteenth node 133 being combined with one another;
slave D-type flip-flop subcircuit:
   the fifth n-channel MOSFET 109, the sixth n-channel MOSFET 110, the seventh n-channel MOSFET 111, the eighth n-channel MOSFET 112, the eleventh n-channel MOSFET 115 and the twelfth n-channel MOSFET 116 clearly form a logic gate, the input signal Q1 provided at the second node 120 and the third node 121 and the clock input signal CLK provided at the fourteenth node 131 and the thirteenth node 133 being combined with one another.

The frequency converter circuit in accordance with FIG. 1 is thus an interconnection of two D-type flip-flops, the output signal of the master D-type flip-flop subcircuit at the second node 120 and the third node 121 being fed into the data input of the slave D-type flip-flop subcircuit and both master D-type flip-flop subcircuit and slave D-type flip-flop subcircuit being controlled by the same clock signal CLK at the thirteenth node 133 and the fourteenth node 131.

The master-slave D-type flip-flop circuit can be interconnected to form a static frequency divider circuit by inverting the signal Q and feeding it with feedback as input signal D to the seventh node 124 and the eighth node 125, the frequency divider circuit converting an input signal CLK having an input frequency to an output signal Q having an output frequency, and the output frequency being half as large as the input frequency.

Furthermore, DE 2 147 795 describes a frequency divider circuit having a flip-flop circuit in which the two inputs of the flip-flop circuit are connected to one another via an inductance, which, with the input capacitances of the flip-flop circuit, form a resonant circuit tuned to approximately half the input frequency. Furthermore, a push-pull output transformer and also DC blocking capacitors are provided in accordance with one embodiment, the DC blocking capacitors being connected between a respective output of the push-pull output transformer and a ground terminal.

### SUMMARY OF THE INVENTION

A frequency converter circuit including at least one frequency converter element and a load stage. The frequency converter elements has at least one signal input and at least one signal output, the frequency converter element being set up such that a signal provided at the signal output has a different signal frequency than a signal fed in at the signal input. The load stage has at least one nonreactive resistor coupled between the frequency converter element and a power feeding terminal and at least one inductance coupled in series with the resistor, and at least one capacitance whose first terminal is coupled between the nonreactive resistor and the inductance and whose second terminal is coupled to a power supply terminal.

### BRIEF DESCRIPTION OF THE DRAWINGS

Exemplary embodiments of the invention are illustrated in the figures and are explained in more detail below. Identical reference symbols designate identical or similar components.

In the figures:

FIG. 1 shows a frequency converter circuit arrangement in accordance with the prior art;

FIG. 2 shows a first circuitry realization of a load stage of frequency converter circuits in accordance with the prior art;

FIG. 3 shows a second circuitry realization of a load stage of frequency converter circuits in accordance with the prior art;

FIG. 4 shows a schematic circuit diagram of a load stage of a frequency converter element in accordance with a first exemplary embodiment of the invention;

FIG. 5 shows a schematic circuit diagram of a load stage of a frequency converter element in accordance with a second exemplary embodiment of the invention;

FIG. 6 shows the magnitude response of the load impedance of frequency converter circuits in accordance with the prior art and in accordance with an exemplary embodiment of the invention in each case as a function of the frequency of the signal fed in;

FIG. 7 shows the phase response of the load impedance of frequency converter circuits in accordance with the prior art and in accordance with an exemplary embodiment of the invention in each case as a function of the frequency of the signal fed in;

FIG. 8 shows a frequency converter circuit arrangement in accordance with an exemplary embodiment of the invention which clearly represents a static current mode logic (CML) frequency divider in NMOS technology. The LCR network illustrated in FIG. 4 is integrated into the frequency converter circuit as a load stage;

FIG. 9 shows a frequency converter circuit arrangement in accordance with an exemplary embodiment of the invention which clearly represents a static frequency divider in emitter coupled logic (ECL). The LCR network illustrated in FIG. 4 is integrated into the frequency converter circuit as a load stage;

FIG. 10 shows a frequency converter circuit arrangement in accordance with an exemplary embodiment of the invention which clearly represents a dynamic frequency divider in bipolar technology. The LCR network illustrated in FIG. 4 is integrated into the frequency converter circuit as a load stage;

FIG. 11 shows a frequency converter circuit arrangement in accordance with an exemplary embodiment of the invention which clearly represents a dynamic frequency divider in NMOS technology. The LCR network illustrated in FIG. 4 is integrated into the frequency converter circuit as a load stage; and

FIG. 12 shows a frequency converter circuit arrangement in accordance with another exemplary embodiment of the invention.

### DETAILED DESCRIPTION OF PREFERRED EMBODIMENTS OF THE INVENTION

The invention is based on the problem of providing a frequency converter circuit and a frequency converter circuit arrangement having a sufficiently large load impedance and also a sufficiently small phase shift of the output signal at high operating frequencies solved by means of a frequency converter circuit and a frequency converter circuit arrangement having the features in accordance with the independent patent claims.

Preferred refinements of the invention emerge from the dependent claims.

The frequency converter circuit has at least one frequency converter element having at least one signal input and a signal output, the frequency converter element being set up in such a way that a signal provided at the signal output has a different signal frequency than a signal fed in at the signal input. Furthermore, at least one nonreactive resistor coupled between the frequency converter element and a power feeding terminal and an inductance coupled in series with said resistor are provided. The frequency converter circuit furthermore has at least one capacitance whose first terminal is coupled between the nonreactive resistor and the inductance and whose second terminal is coupled to a power supply terminal.

In one embodiment of the invention, the capacitance is coupled in parallel with the nonreactive resistor and preferably coupled to a positive power supply terminal. In an alternative embodiment of the invention, the capacitance is coupled to a negative power supply terminal by its second terminal.

A frequency converter circuit arrangement has at least two frequency converter circuits such as have been described above which are coupled in series with one another.

In particular by means of the additional capacitance, a functional operation of the frequency converter circuit and of the frequency converter circuit arrangement is thus ensured according to the invention even at high frequencies.

Clearly, what is achieved by the invention is that both the magnitude and the phase shift of a load impedance are considerably improved.

One refinement of the invention provides at least one additional inductance which is connected in series between the inductance and the nonreactive resistor. Furthermore, this refinement of the invention provides at least one additional capacitance which, by way of example, is coupled in parallel with the additional inductance and whose first terminal is coupled between the inductance and the additional inductance and whose second terminal is coupled to the power supply terminal.

The frequency converter circuit is preferably set up as a frequency divider circuit, particularly preferably as a static frequency divider circuit, alternatively as a dynamic frequency divider circuit.

In accordance with one development of the invention, the frequency divider circuit set up as a dynamic frequency divider circuit is designed as a so-called Gilbert cell.

The frequency converter element may have at least one flip-flop circuit, the frequency converter element preferably having at least one D-type flip-flop circuit, alternatively at least one JK flip-flop circuit.

In accordance with another refinement of the invention, the frequency converter element contains MOS transistors, preferably NMOS transistors and/or PMOS transistors.

In accordance with another refinement of the invention, the frequency converter element has transistors connected up to one another in emitter coupled logic (ECL).

FIG. 4 shows a schematic circuit diagram of a load stage of a frequency converter element in accordance with a first exemplary embodiment of the invention.

An inductance 402 is arranged between a first node 405 and a second node 406. A capacitance 404 is arranged between the second node 406 and a third node 407. A nonreactive resistor 403 is arranged between the second node 406 and the third node 407. A fictitious parasitic capacitance 401 is arranged between the first node 405 and the third node 407. While the third node 407 is grounded, the load stage is coupled to the second stage of the frequency converter element at the first node 405.

The parasitic effects of a frequency converter element are taken into account in the form of the fictitious parasitic capacitance 401 in the load stage of the frequency converter circuit. The nonreactive resistor 403 serves as load resistor of a frequency converter element described below.

In addition to the inductance 402 the capacitance 404 is provided, which has the effect that, on the one hand, the magnitude of the load impedance of the frequency converter element is kept large preferably at high operating frequencies and, on the other hand, the phase shift of the load impedance of the frequency converter element is kept small preferably at high operating frequencies.

FIG. 5 shows a schematic circuit diagram of a load stage of a frequency converter element in accordance with a second exemplary embodiment of the invention.

A first inductance 502 is arranged between a first node 507 and a second node 508. A second inductance 503 is arranged between the second node 508 and a third node 509. A first capacitance 504 is arranged between the second node 508 and a fourth node 510. A nonreactive resistor 505 is arranged between the third node 509 and the fourth node 510. A second capacitance 506 is arranged between the third node 509 and the fourth node 510. A fictitious parasitic capacitance 501 is arranged between the first node 507 and the fourth node 510. While the fourth node 510 is at ground potential, the load stage is coupled to the second stage of the frequency converter element at the first node 507.

The influence of the first capacitance 504 and of the second capacitance 506 on the magnitude and the phase of the load impedance of the frequency converter element preferably at high operating frequencies leads to significant improvements compared with a frequency converter load stage circuit in accordance with the prior art, as is illustrated for example in FIG. 3, both with regard to the magnitude response of the load impedance of the frequency converter element and with regard to the phase response of the load impedance of the frequency converter element.

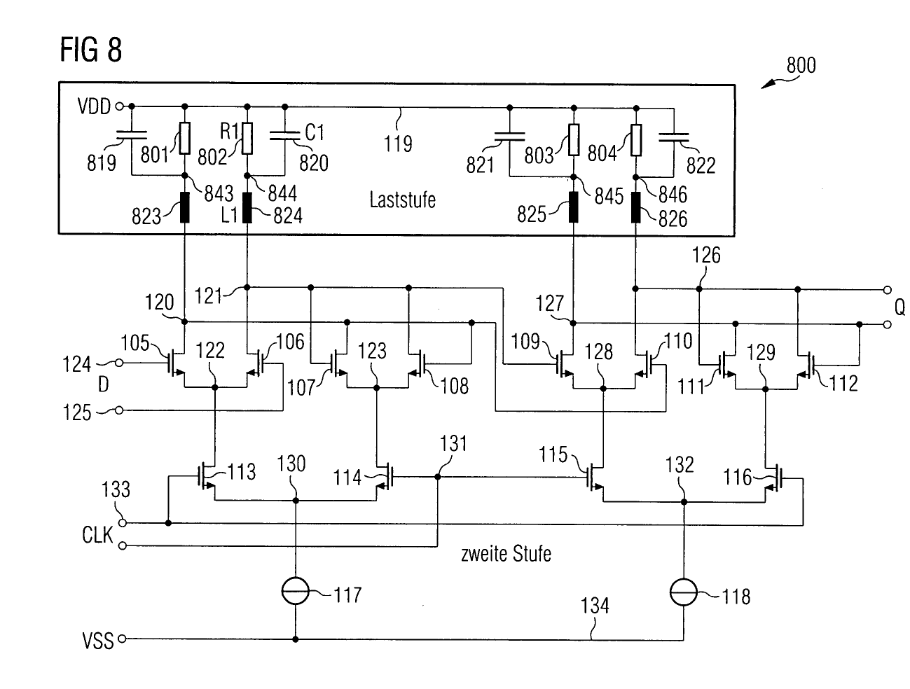

FIG. 8 shows a frequency converter circuit arrangement 800 in accordance with an exemplary embodiment of the invention which clearly represents a static current mode logic (CML) frequency divider in NMOS technology.

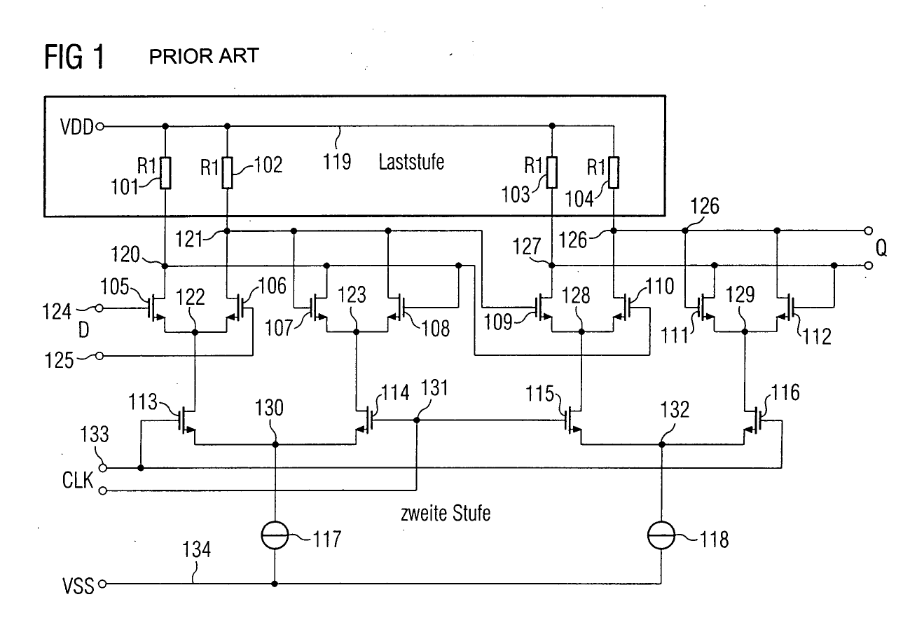

The frequency converter circuit arrangement 800 in accordance with FIG. 8 clearly corresponds to the circuit in accordance with FIG. 1, but has the additional elements described below.

A seventeenth node 843 is provided between the first node 119 and the second node 120. An eighteenth node 844 is provided between the first node 119 and the third node 121. A nineteenth node 845 is provided between the first node 119 and the fourth node 127. A twentieth node 846 is provided between the first node 119 and the fifth node 126. A first nonreactive resistor 801 is arranged between the first node 119 and the seventeenth node 843. A second nonreactive resistor 802 is arranged between the first node 119 and the eighteenth node 844. A third nonreactive resistor 803 is arranged between the first node 119 and the nineteenth node 845. A fourth nonreactive resistor 804 is arranged between the first node 119 and the twentieth node 846. A first inductance 823 is arranged between the seventeenth node 843 and the second node 120. A second inductance 824 is arranged between the eighteenth node 844 and the third node 121. A third inductance 825 is arranged between the nineteenth node 845 and the fourth node 127. A fourth inductance 826 is arranged between the twentieth node 846 and the fifth node 126. A first capacitance 819 is arranged between the first node 119 and the seventeenth node 843. A second capacitance 820 is arranged between the first node 119 and the eighteenth node 844. A third capacitance 821 is arranged between the first node 119 and the nineteenth node 845. A fourth capacitance 822 is arranged between the first node 119 and the twentieth node 846.

The load stage of the frequency converter circuit in accordance with FIG. 8 has the first nonreactive resistor 801, the second nonreactive resistor 802, the third nonreactive resistor 803, the fourth nonreactive resistor 804, the first inductance 823, the second inductance 824, the third inductance 825, the fourth inductance 826, and also the first capacitance 819, the second capacitance 820, the third capacitance 821 and the fourth capacitance 822.

The load stage of the frequency converter circuit in accordance with FIG. 8 has four load stages such as have been described in connection with FIG. 4, all four load stages in accordance with FIG. 4 being coupled to the third node 407 and a respective first node 405 of a load stage in accordance with FIG. 4 being coupled to the second stage of the frequency converter circuit in accordance with FIG. 8.

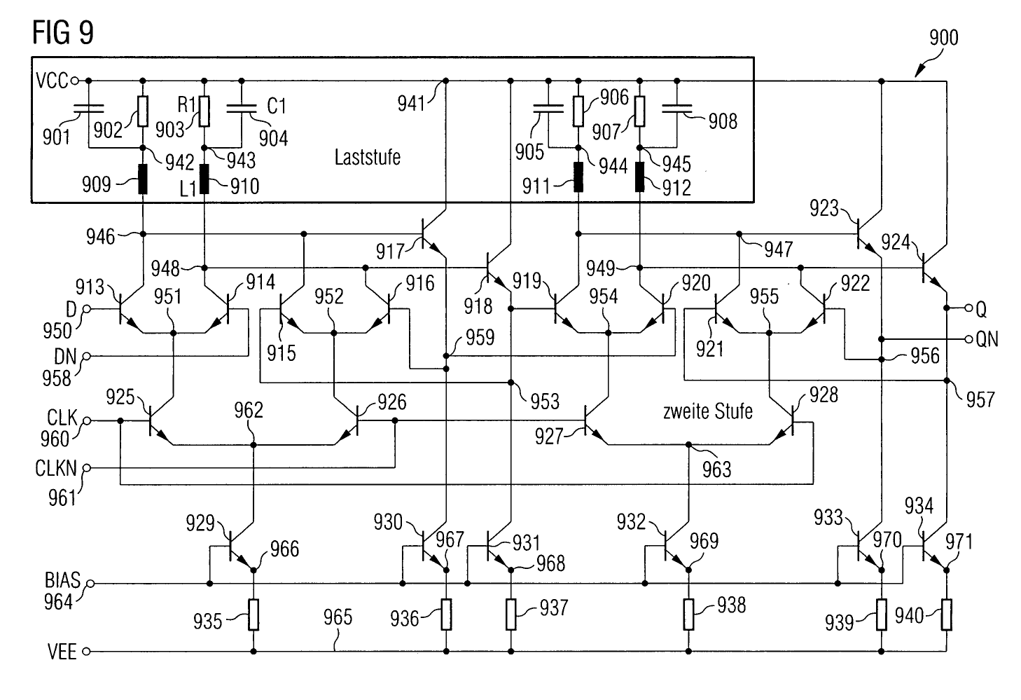

FIG. 9 shows a frequency converter circuit arrangement 900 in accordance with a second exemplary embodiment of the invention which represents a static frequency divider in emitter coupled logic (ECL).

A first capacitance 901 is arranged between a first node 941 and a second node 942. A second capacitance 904 is arranged between the first node 941 and a third node 943. A third capacitance 905 is arranged between the first node 941 and a fourth node 944. A fourth capacitance 908 is arranged between the first node 941 and a fifth node 945. A first nonreactive resistor 902 is arranged between the first node 941 and the second node 942. A second nonreactive resistor 903 is arranged between the first node 941 and the third node 943. A third nonreactive resistor 906 is arranged between the first node 941 and the fourth node 944. A fourth nonreactive resistor 907 is arranged between the first node 941 and the fifth node 945. A fifth nonreactive resistor 935 is arranged between a sixth node 966 and a seventh node 965. A sixth nonreactive resistor 936 is arranged between an eighth node 967 and the seventh node 965. A seventh nonreactive resistor 937 is arranged between a ninth node 968 and the seventh node 965. An eighth nonreactive resistor 938 is arranged between a tenth node 969 and the seventh node 965. A ninth nonreactive resistor 939 is arranged between an eleventh node 970 and the seventh node 965. A tenth nonreactive resistor 940 is arranged between a twelfth node 971 and the seventh node 965. A first inductance 909 is arranged between the second node 942 and a thirteenth node 946. A second inductance 910 is arranged between the third node 943 and a fourteenth node 948. A third inductance 911 is arranged between the fourth node 944 and a fifteenth node 947. A fourth inductance 912 is arranged between the fifth node 945 and a sixteenth node 949. A collector-emitter region of a first npn bipolar transistor 913 is arranged between the thirteenth node 946 and a seventeenth node 951. A base region of the first npn bipolar transistor 913 is connected to an eighteenth node 950. A collector-emitter region of a second npn bipolar transistor 914 is arranged between the fourteenth node 948 and the seventeenth node 951. A base region of the second npn bipolar transistor 914 is connected to a nineteenth node 958. A collector-emitter region of a third npn bipolar transistor 915 is arranged between the thirteenth node 946 and a twentieth node 952. A base region of the third npn bipolar transistor 915 is connected to a twenty-first node 953. A collector-emitter region of a fourth npn bipolar transistor 916 is arranged between the fourteenth node 948 and the twentieth node 952. A base region of the fourth npn bipolar transistor 916 is connected to a twenty-second node 959. A collector-emitter region of a fifth npn bipolar transistor 917 is arranged between the first node 941 and the twenty-second node 959. A base region of the fifth npn bipolar transistor 917 is connected to the thirteenth node 946. A collector-emitter region of a sixth npn bipolar transistor 918 is arranged between the first node 941 and the twenty-first node 953. A base region of the sixth npn bipolar transistor 918 is connected to the fourteenth node 948. A collector-emitter region of a seventh npn bipolar transistor 919 is arranged between the fifteenth node 947 and a twenty-third node 954. A base region of the seventh npn bipolar transistor 919 is connected to the twenty-first node 953. A collector-emitter region of an eighth npn bipolar transistor 920 is arranged between the sixteenth node 949 and the twenty-third node 954. A base region of the eighth npn bipolar transistor 920 is connected to the twenty-second node 959. A collector-emitter region of a ninth npn bipolar transistor 921 is arranged between the sixteenth node 949 and a twenty-fourth node 955. A base region of the ninth npn bipolar transistor 921 is connected to a twenty-fifth node 957. A collector-emitter region of a tenth npn bipolar transistor 922 is arranged between the sixteenth node 949 and the twenty-fourth node 955. A base region of the tenth npn bipolar transistor 922 is connected to a twenty-sixth node 956. A collector-emitter region of an eleventh npn bipolar transistor 923 is arranged between the first node 941 and the twenty-sixth node 956. A base region of the eleventh npn bipolar transistor 923 is connected to the fifteenth node 947. A collector-emitter region of a twelfth npn bipolar transistor 924 is arranged between the first node 941 and the twenty-fifth node 957. A base region of the twelfth npn bipolar transistor 924 is connected to the sixteenth node 949. A collector-emitter region of a thirteenth npn bipolar transistor 925 is arranged between the seventeenth node 951 and a twenty-seventh node 962. A base region of the thirteenth npn bipolar transistor 925 is connected to a twenty-eighth node 960. A collector-emitter region of a fourteenth npn bipolar transistor 926 is arranged between the twentieth node 952 and the twenty-seventh node 962. A base region of the fourteenth npn bipolar transistor 926 is connected to a twenty-ninth node 961. A collector-emitter region of a fifteenth npn bipolar transistor 927 is arranged between the twenty-third node 954 and a thirtieth node 963. A base region of the fifteenth npn bipolar transistor 927 is connected to the twenty-ninth node 961. A collector-emitter region of a sixteenth npn bipolar transistor 928 is arranged between the twenty-fourth node 955 and the thirtieth node 963. A base region of the sixteenth npn bipolar transistor 928 is connected to the twenty-eighth node 960. A collector-emitter region of a seventeenth npn bipolar transistor 929 is arranged between the twenty-seventh node 962 and the sixth node 966. A base region of the seventeenth npn bipolar transistor 929 is connected to a thirty-first node 964. A collector-emitter region of an eighteenth npn bipolar transistor 930 is arranged between the twenty-second node 959 and the eighth node 967. A base region of the eighteenth npn bipolar transistor 930 is connected to the thirty-first node 964. A collector-emitter region of a nineteenth npn bipolar transistor 931 is arranged between the twenty-first node 953 and the ninth node 968. A base region of the nineteenth npn bipolar transistor 931 is connected to the thirty-first node 964. A collector-emitter region of a twentieth npn bipolar transistor 932 is arranged between the thirtieth node 963 and the tenth node 969. A base region of the twentieth npn bipolar transistor 932 is connected to the thirty-first node 964. A collector-emitter region of a twenty-first npn bipolar transistor 933 is arranged between the twenty-sixth node 956 and the eleventh node 970. A base region of the twenty-first npn bipolar transistor 933 is connected to the thirty-first node 964. A collector-emitter region of a twenty-second npn bipolar transistor 934 is arranged between the twenty-fifth node 957 and the twelfth node 971. A base region of the twenty-second npn bipolar transistor 934 is connected to the thirty-first node 964. A signal VCC is provided at the first node 941, VCC representing a supply voltage of the frequency converter circuit. A signal D is provided at the eighteenth node 950. A signal DN is provided at the nineteenth node 958. A signal CLK is provided at the twenty-eighth node 960, the signal CLK representing a clock signal. A signal CLKN is provided at the twenty-ninth node 961. A signal BIAS is provided at the thirty-first node 964, BIAS being a voltage that puts the frequency converter circuit at the operating point. A signal VEE is provided at the seventh node 965, VEE representing a further supply voltage of the frequency converter circuit. A signal Q is output at the twenty-fifth node 957. A signal QN is output at the twenty-sixth node 956. The frequency converter circuit in accordance with FIG. 9 clearly represents a single-edge-triggered master-slave D-type flip-flop circuit.

The load stage of the frequency converter circuit in accordance with FIG. 9 is isolated from the second stage of the frequency converter circuit in accordance with FIG. 9 by the thirteenth node 946, the fourteenth node 948, the first node 941, the fifteenth node 947 and the sixteenth node 949.

The load stage of the frequency converter circuit in accordance with FIG. 9 has the first nonreactive resistor 902, the second nonreactive resistor 903, the third nonreactive resistor 906 and the fourth nonreactive resistor 907, the first inductance 909, the second inductance 910, the third inductance 911 and the fourth inductance 912 and also the first capacitance 901, the second capacitance 904, the third capacitance 905 and the fourth capacitance 908.

The load stage of the frequency converter circuit in accordance with FIG. 9 has four load stages as illustrated in FIG. 4, all four load stages in accordance with FIG. 4 being coupled to the third node 407 and a respective first node 405 of a load stage in accordance with FIG. 4 being coupled to the second stage of the frequency converter circuit in accordance with FIG. 9.

The second stage in accordance with FIG. 9 can be decomposed into the following subcircuits:
differential amplifiers, the second stage having the following differential amplifiers:
   a first differential amplifier having a first npn bipolar transistor 913 and a second npn bipolar transistor 914;
   a second differential amplifier having a third npn bipolar transistor 915 and a fourth npn bipolar transistor 916;
   a third differential amplifier having a thirteenth npn bipolar transistor 925 and a fourteenth npn bipolar transistor 926;
   a fourth differential amplifier having a seventh npn bipolar transistor 919 an eighth npn bipolar transistor 920;
   a fifth differential amplifier having a ninth npn bipolar transistor 921 and a tenth npn bipolar transistor 922;
   a sixth differential amplifier having a fifteenth npn bipolar transistor 927 and a sixteenth npn bipolar transistor 928;
voltage controlled current sources, the second stage having the following voltage controlled current sources:
   a first voltage controlled current source having a seventeenth npn bipolar transistor 929 and a fifth nonreactive resistor 935;
   a second voltage controlled current source having an eighteenth npn bipolar transistor 930 and a sixth nonreactive resistor 936;
   a third voltage controlled current source having a nineteenth npn bipolar transistor 931 and a seventh nonreactive resistor 937;
   a fourth voltage controlled current source having a twentieth npn bipolar transistor 932 and an eighth nonreactive resistor 938;
   a fifth voltage controlled current source having a twenty-first npn bipolar transistor 933 and a ninth nonreactive resistor 939;
   a sixth voltage controlled current source having a twenty-second npn bipolar transistor 934 and a tenth nonreactive resistor 940.

The seventeenth npn bipolar transistor 929, the eighteenth npn bipolar transistor 930, the nineteenth npn bipolar transistor 931, the twentieth npn bipolar transistor 932, the twenty-first npn bipolar transistor 933 and the twenty-second npn bipolar transistor 934 are put at the operating point by means of the BIAS and operated at said operating point.

The master D-type flip-flop subcircuit outputs the signal Q1 at the twenty-first node 953 and the inverted signal Q1N with respect to the signal Q1 at the twenty-second node 959. The input nodes of the slave D-type flip-flop subcircuit are the twenty-first node 953 and the twenty-second 959; the signals Q1 and Q1 are thus fed into the slave D-type flip-flop subcircuit as input signals D2 and DN2. The clock signal CLK and also the inverted clock signal CLKN with respect to the signal CLK control the master D-type flip-flop subcircuit and simultaneously the slave D-type flip-flop subcircuit.

The single-edge-triggered master-slave D-type flip-flop circuit thus represents a frequency divider circuit which outputs the input signal D provided at the eighteenth node 950 in the form of the signal Q at the twenty-fifth node 957 upon clock edges of the trigger signal provided at the twenty-eighth node 960.

If an input signal D has an input frequency, then the output signal Q has an output frequency that is half as large as the input frequency. The master-slave D-type flip-flop circuit thus clearly represents a frequency divider circuit that halves the input frequency.

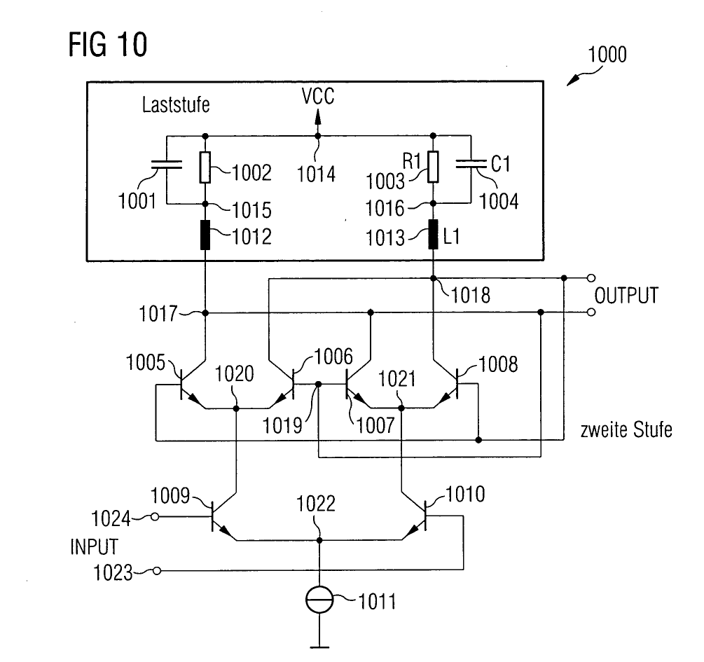

FIG. 10 shows a frequency converter circuit arrangement 1000 in accordance with an exemplary embodiment of the invention which represents a dynamic frequency divider in bipolar technology.

In the frequency converter circuit arrangement 1000 a first nonreactive resistor 1002 is arranged between a first node 1014 and a second node 1015. A second nonreactive resistor 1003 is arranged between the first node 1014 and a third node 1016. A first capacitance 1001 is arranged between the first node 1014 and the second node 1015. A second capacitance 1004 is arranged between the first node 1014 and the third node 1016. A first inductance 1012 is arranged between the second node 1015 and a fourth node 1017. A second inductance 1013 is arranged between the third node 1016 and fifth node 1018. A collector-emitter region of a first npn bipolar transistor 1005 is arranged between the fourth node 1017 and a sixth node 1020. A base region of the first npn bipolar transistor 1005 is connected to the fifth node 1018. A collector-emitter region of a second npn bipolar transistor 1006 is arranged between the fifth node 1018 and the sixth node 1020. A base region of the second npn bipolar transistor 1006 is connected to a seventh node 1019. A collector-emitter region of a third npn bipolar transistor 1007 is arranged between the fourth node 1017 and an eighth node 1021. A base region of the third npn bipolar transistor 1007 is connected to the seventh node 1019. A collector-emitter region of a fourth npn bipolar transistor 1008 is arranged between the fifth node 1018 and the eighth node 1021. A base region of the fourth npn bipolar transistor 1008 is connected to the fifth node 1018. A collector-emitter region of a fifth npn bipolar transistor 1009 is arranged between the sixth node 1020 and a ninth node 1022. A base region of the fifth npn bipolar transistor 1009 is connected to a tenth node 1024. A collector-emitter region of a sixth npn bipolar transistor 1010 is arranged between the eighth node 1021 and the ninth node 1022. A base region of the sixth npn bipolar transistor 1010 is connected to an eleventh node 1023. A constant-current source 1011 is arranged between the ninth node 1022 and ground. A supply voltage signal V_{CC} is provided at the first node 1014. An input signal INPUT is provided at the tenth node 1024 and at the eleventh node 1023. An output signal OUTPUT is output at the fourth node 1017 and at the fifth node 1018.

The load stage of the frequency converter circuit in accordance with FIG. 10 is isolated from the second stage of the frequency converter circuit in accordance with FIG. 10 by the fourth node 1017 and the fifth node 1018.

load stage of the frequency converter circuit in accordance with FIG. 10 has the first nonreactive resistor 1002 and the second nonreactive resistor 1003, the first inductance 1012 and the second inductance 1013 and also the first capacitance 1001 and the second capacitance 1004.

The load stage of the frequency converter circuit in accordance with FIG. 10 has two load stages in accordance with FIG. 4, both load stages in accordance with FIG. 4 being coupled to the third node 407 and a respective first node 405 of a load stage in accordance with FIG. 4 being coupled to the second stage in accordance with FIG. 10.

The second stage of the dynamic frequency divider in accordance with FIG. 10 differs from the second stage of the static frequency divider in accordance with FIG. 9 in terms of the following elements:

the second differential amplifier and the fifth differential amplifier of the arrangement 900 in accordance with FIG. 9 including the elements which control them are emitted. The third differential amplifier and the sixth differential amplifier are combined to form a new differential amplifier, which is represented in FIG. 10 in the form of the fifth npn bipolar transistor 1009 and the sixth npn bipolar transistor 1010.

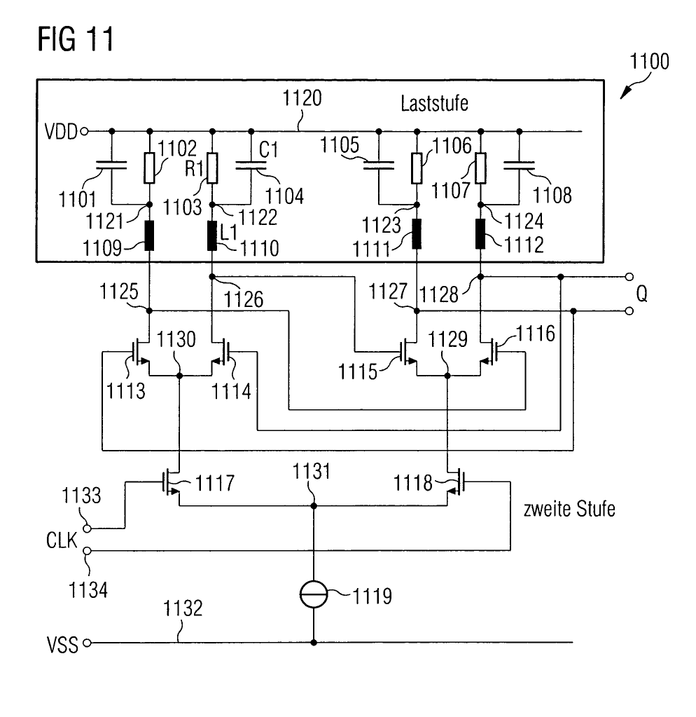

FIG. 11 shows a frequency converter circuit arrangement 1100 in accordance with a further exemplary embodiment of the invention which represents a dynamic frequency divider in NMOS technology.

The frequency converter circuit arrangement 1100 has a first capacitance 1101 arranged between a first node 1120 and a second node 1121. A second capacitance 1104 is arranged between the first node 1120 and a third node 1122. A third capacitance 1105, is arranged between the first node 1120 and a fourth node 1123. A fourth capacitance 1108 is arranged between the first node 1120 and a fifth node 1124. A first nonreactive resistor 1102 is arranged between the first node 1120 and the second node 1121. A second nonreactive resistor 1103 is arranged between the first node 1120 and the third node 1122. A third nonreactive resistor 1106 is arranged between the first node 1120 and the fourth node 1123. A fourth nonreactive resistor 1107 is arranged between the first node 1120 and the fifth node 1124. A first inductance 1109 is arranged between the second node 1121 and a sixth node 1125. A second inductance 1110 is arranged between the third node 1122 and a seventh node 1126. A third inductance 1111 is arranged between the fourth node 1123 and an eighth node 1127. A fourth inductance 1112 is arranged between the fifth node 1124 and a ninth node 1128. A drain/source region of a first n-channel MOSFET 1113 is arranged between the sixth node 1125 and a tenth node 1130. A gate region of the first n-channel MOSFET 1113 is connected to the eighth node 1127. A drain/source region of a second n-channel MOSFET 1114 is arranged between the seventh node 1126 and the tenth node 1130. A gate region of the second n-channel MOSFET 1114 is connected to the ninth node 1128. A drain/source region of a third n-channel MOSFET 1115 is arranged between the eighth node 1127 and an eleventh node 1129. A gate region of the third n-channel MOSFET 1115 is connected to the seventh node 1126. A drain/source region of a fourth n-channel MOSFET 1116 is arranged between the ninth node 1128 and the eleventh node 1129. A gate region of the fourth n-channel MOSFET 1116 is connected to the sixth node 1125. A drain/source region of a fifth n-channel MOSFET 1117 is arranged between the tenth node 1130 and a twelfth node 1131. A gate region of the fifth n-channel MOSFET 1117 is connected to a thirteenth node 1133. A drain/source region of a sixth n-channel MOSFET 1118 is arranged between the eleventh node 1129 and the twelfth node 1131. A gate region of the sixth n-channel MOSFET 1118 is connected to a fourteenth node 1134. A constant-current source 1119 is arranged between the twelfth node 1131 and a fifteenth node 1132. A signal FIG. is provided at the first node 1120, FIG. representing a supply voltage of the frequency converter circuit. A signal CLK is provided at the thirteenth node 1133 and at the fourteenth node 1134, the signal CLK representing a clock signal. A signal VSS is provided at the fifteenth node 1132, VSS representing a further supply voltage of the frequency converter circuit. A signal Q is output at the ninth node 1128 and at the eighth node 1127.

The load stage of the frequency converter circuit in accordance with FIG. 11 is isolated from the second stage of the frequency converter circuit in accordance with FIG. 11 by the sixth node 1125, the seventh node 1126, the eighth ,node 1127 and the ninth node 1128.

The load stage of the frequency converter circuit in accordance with FIG. 11 has the first nonreactive resistor 1102, the second nonreactive resistor 1103, the third nonreactive resistor 1106 and the fourth nonreactive resistor 1107, the first inductance 1109, the second inductance 1110, the third inductance 1111, the fourth inductance 1112 and also the first capacitance 1101, the second capacitance 1104, the third capacitance 1105 and the fourth capacitance 1108.

The load stage of the frequency converter circuit in accordance with FIG. 11 has four load stages set up in accordance with FIG. 4, all four load stages in accordance with FIG. 4 being coupled to the third node 407 and a respective first node 405 of a load stage in accordance with FIG. 4 being coupled to the second stage in accordance with FIG. 11.

The second stage of the dynamic frequency divider circuit in accordance with FIG. 11 differs from the second stage of the static frequency divider circuit in accordance with FIG. 8 in terms of the following elements:

as soon as, in accordance with FIG. 8, the data input D can no longer follow the clock signal CLK on account of the switching times of the third n-channel MOSFET 107, of the fourth n-channel MOSFET 108, of the tenth n-channel MOSFET 114 and of the seventh n-channel MOSFET 111, of the eighth n-channel MOSFET 112 and of the twelfth n-channel MOSFET 116, the control effect of the third n-channel MOSFET 107, of the fourth n-channel MOSFET 108, of the tenth n-channel MOSFET 114 and of the seventh n-channel MOSFET 111, of the eighth n-channel MOSFET 112 and of the twelfth n-channel MOSFET 116 is obviated and they can be omitted, the n-channel MOSFET 105, the n-channel MOSFET 106, the n-channel MOSFET 109, the n-channel MOSFET 110, the n-channel MOSFET 113 and the n-channel MOSFET 115 being combined to form a logic gate which can be seen in the form of the first n-channel MOSFET 1113 and the sixth n-channel MOSFET 1118 in FIG. 11.

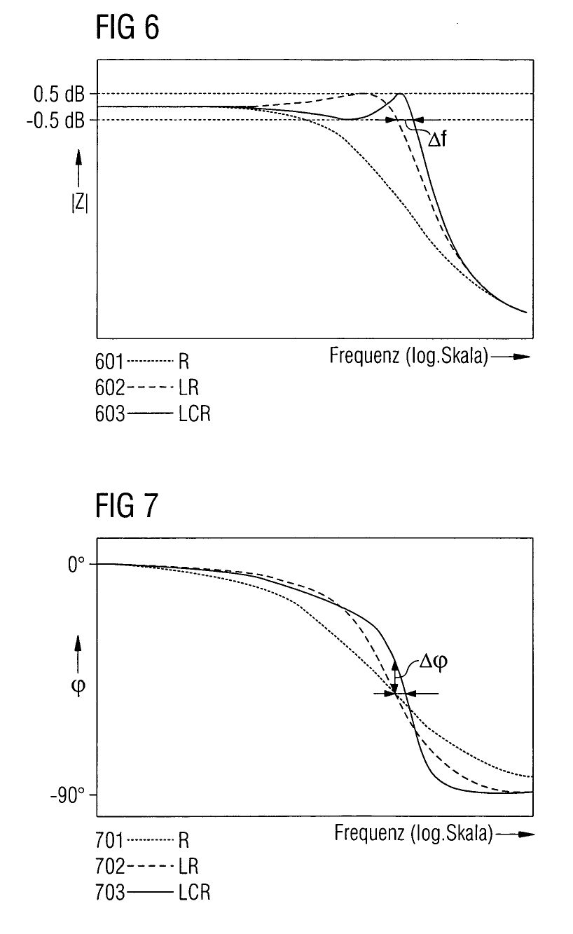

The magnitude response of the load impedance of three different frequency converter circuits in each case as a function of the frequency of the signal fed in is illustrated in FIG. 6, the three frequency converter circuits considered preferably differing with regard to the circuit design of their load stages:

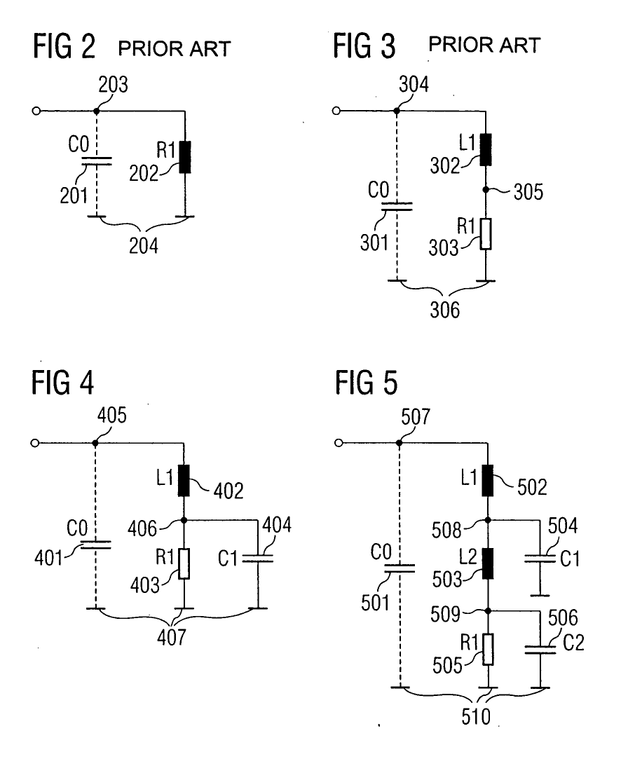

the line designated by the reference symbol 601 shows the frequency-dependent magnitude response of a load impedance of a frequency converter circuit whose load stages are constructed in accordance with FIG. 2.

The line designated by the reference symbol 602 shows the frequency-dependent magnitude response of a load impedance of a frequency converter circuit whose load stages are constructed in accordance with FIG. 3.

The line designated by the reference symbol 603 shows the frequency-dependent magnitude response of a load impedance of a frequency converter circuit whose load stages are constructed in accordance with the invention according to FIG. 4, a significantly higher magnitude level of the load impedance of the frequency converter circuits distinctly being discernible here at high frequencies.

The embodiment of a frequency converter circuit according to the invention has the advantage in accordance with FIG. 6 that the operating frequency of the frequency converter circuit can be increased by the frequency interval Δf if the magnitude of the load impedance is intended to vary only within a 0.5 dB strip about the magnitude of the load impedance of the frequency converter circuit operated at low operating frequencies, in the frequency converter circuit preferably load stages in accordance with FIG. 3 being converted into load stages in accordance with FIG. 4 according to the invention.

The phase response of the load impedance of three different frequency converter circuits in each case as a function of the frequency of the signal fed in is illustrated in FIG. 7, the three frequency converter circuits considered preferably differing with regard to the circuit design of their load stages:

the line designated by the reference symbol 701 shows the frequency-dependent phase response of a load impedance of a frequency converter circuit whose load stages are constructed in accordance with FIG. 2.

The line designated by the reference symbol 702 shows the frequency-dependent phase response of a load impedance of a frequency converter circuit whose load stages are constructed in accordance with FIG. 3.

The line designated by the reference symbol 703 shows the frequency-dependent phase response of a load impedance of a frequency converter circuit whose load stages are constructed in accordance with the invention according to FIG. 4, a significantly lower phase shift of the load impedance of the frequency converter circuits distinctly being discernible here at high operating frequencies of a frequency converter circuit which lie in the Δf range in accordance with FIG. 6.

The embodiment of a frequency converter circuit according to the invention furthermore has the advantage, as illustrated in FIG. 7, that the phase shift of the load impedance of a frequency converter circuit is lower by the phase shift interval Δφ if, at the same high operating frequency which preferably lies around the Δf range in accordance with FIG. 6, in the frequency converter circuit load stages in accordance with FIG. 3 are converted into load stages in accordance with FIG. 4 according to the invention.

To summarize, it should be noted that, as can be seen in FIG. 6 and in FIG. 7, the invention's configuration of a load stage of a frequency converter circuit in accordance with FIG. 4 or FIG. 5 exhibits significant improvements in comparison with the prior art in accordance with FIG. 2 and FIG. 3 with regard to the desired magnitude response of the load impedance and with regard to the phase shift of the output signal preferably at high operating frequencies.

To summarize, what is common to the exemplary embodiments illustrated in FIG. 8 to FIG. 11 is, in particular, that the capacitances C1 819, 820, 821, 822, 901, 904, 905, 908, 1001, 1004, 1101, 1104, 1105, 1108 connected in parallel with the nonreactive resistors are connected by their first terminal between the respective inductance and the nonreactive resistor and are coupled by their second terminal to the positive supply voltage V_{CC} or V_{DD}.

However, it should be pointed out that this is not absolutely necessary. In alternative configurations of the invention, it is equally possible and provided that the second terminal of the additional capacitances C1 819, 820, 821, 822, 901, 904, 905, 908, 1001, 1004, 1101, 1104, 1105, 1108 is coupled to the supply voltage V_{EE} or V_{SS} and, consequently, they can no longer be connected in parallel with the nonreactive resistors.

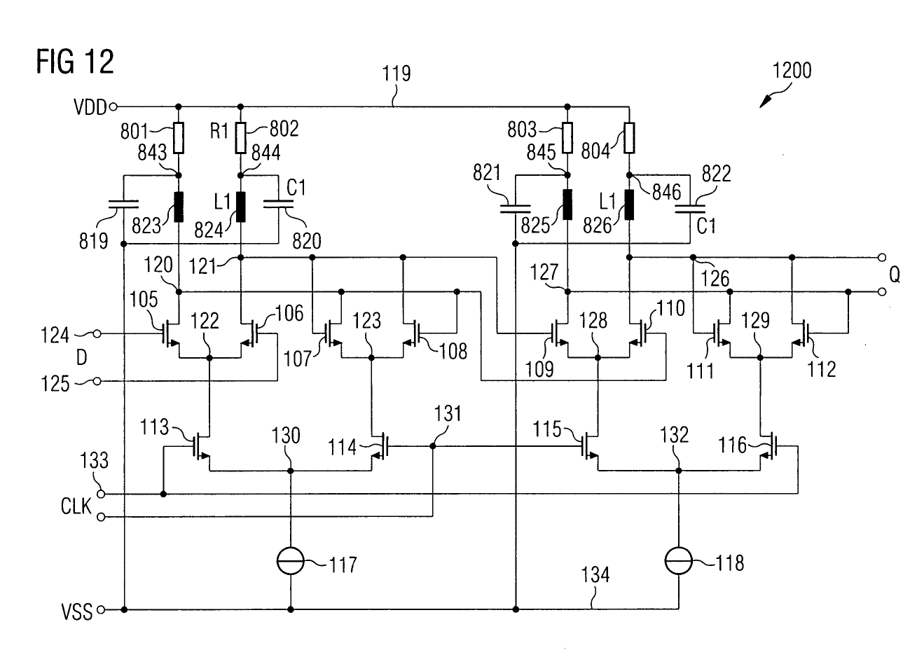

Such an alternative embodiment of a frequency converter circuit arrangement 1200, which corresponds to the embodiment illustrated in FIG. 8 apart from the aspect described, is illustrated in FIG. 12. In contrast to the frequency converter circuit arrangement 800 illustrated in FIG. 8, the second terminal of the respective capacitances 819, 820, 821, 822 of the frequency converter circuit arrangement 1200 is coupled to the sixteenth node 134 and thus to the negative power supply potential V_{SS}.

In a corresponding manner, alternative embodiments of frequency converter circuit arrangements are provided which essentially correspond in each case to the frequency converter circuit arrangements 900, 1000, 1100 illustrated in FIG. 9, FIG. 10 and FIG. 11 with the difference that the second terminal of the respective capacitances (capacitances 901, 904, 905, 908 of the frequency converter circuit arrangement 900, capacitances 1001, 1004 of the frequency converter circuit arrangement 1000, capacitances 1101, 1104, 1105, 1108 of the frequency converter circuit arrangement 1100) is coupled to the respective negative power supply potential V_{SS}.

1-15. (canceled)

16. A frequency converter circuit comprising:
at least one frequency converter element having at least one signal input and at least one signal output, the frequency converter element being set up such that a signal provided at the signal output has a different signal frequency than a signal fed in at the signal input; and
a load stage comprising:
at least one nonreactive resistor coupled between the frequency converter element and a power feeding terminal and at least one inductance coupled in series with said resistor; and
at least one capacitance whose first terminal is coupled between the nonreactive resistor and the inductance and whose second terminal is coupled to a power supply terminal.

17. The frequency converter circuit as claimed in claim 16, wherein the load stage further comprises:
at least one additional inductance connected in series between the at least one inductance and the nonreactive resistor; and
at least one additional capacitance whose first terminal is coupled between the at least one inductance and the additional inductance and whose second terminal is coupled to the power supply terminal.

18. The frequency converter circuit as claimed in claim 16, set up as a frequency divider circuit.

19. The frequency converter circuit as claimed in claim 18, wherein the frequency divider circuit is set up as a static frequency divider circuit.

20. The frequency converter circuit as claimed in claim 18, wherein the frequency divider circuit is set up as a dynamic frequency divider circuit.

21. The frequency converter circuit as claimed in claim 20, wherein the dynamic frequency divider circuit is set up as a Gilbert cell.

22. The frequency converter circuit as claimed in claim 16, wherein the frequency converter element has at least one flip-flop circuit.

23. The frequency converter circuit as claimed in claim 22, wherein the frequency converter element has at least one D type flip-flop circuit.

24. The frequency converter circuit as claimed in claim 22, wherein the frequency converter element has at least one JK flip-flop circuit.

25. The frequency converter circuit as claimed in claim 16, wherein the frequency converter element has MOS transistors.

26. The frequency converter circuit as claimed in claim 25, wherein the frequency converter element has NMOS transistors.

27. The frequency converter circuit as claimed in claim 25, wherein the frequency converter element has PMOS transistors.

28. The frequency converter circuit as claimed in claim 19, wherein the frequency converter element has transistors connected to one another in emitter coupled logic (ECL).

29. The frequency converter circuit as claimed in claim 16, wherein the second terminal of the at least one capacitance is coupled to a positive power supply terminal or to a negative power supply terminal.

30. A frequency converter circuit arrangement having at least two frequency converter circuits as claimed in claim 16 and which are coupled in series with one another.

31. The frequency converter circuit as claimed in claim 25, wherein the frequency converter element has bipolar transistors.

32. A load stage of a frequency converter circuit, comprising:
at least one nonreactive resistor coupled between a frequency converter element and a power feeding terminal and at least one inductance coupled in series with the resistor; and
at least one capacitance whose first terminal is coupled between the nonreactive resistor and the inductance and whose second terminal is coupled to a power supply terminal.

33. The load stage as claimed in claim 32, further comprising:
at least one additional inductance connected in series between the at least one inductance and the nonreactive resistor; and
at least one additional capacitance whose first terminal is coupled between the at least one inductance and the additional inductance and whose second terminal is coupled to the power supply terminal.
